(19) United States
(12) Patent Application Publication
(10) Pub. No.: US 2007/0002634 A1
(43) Pub. Date: Jan. 4, 2007

(54) System and method of transmitting data in an electronic circuit

(76) Inventor: Luc Montperrus, Montigny Le Bretonneux (FR)

Correspondence Address: MEYERTONS, HOOD, KIVLIN, KOWERT & GOETZEL, P.C., 700 LAVACA, SUITE 800, AUSTIN, TX, 78701, US

(21) Appl. No.: 11/179,014

(22) Filed: Jul. 11, 2005

(30) Foreign Application Priority Data
Jun. 10, 2005 (FR) FR 0505896

(51) Int. Cl. G11C 7/10

(52) U.S. Cl. 365/189.01

(57) ABSTRACT

System of transmitting data in an electronic circuit, comprising a set of signal transmission lines disposed roughly parallel to each other, each transmission line comprising inverting and non-inverting signal regeneration elements. Said set of transmission lines comprises four subsets of lines, each of which comprises at least one transmission line provided with a periodic arrangement of said inverting and non-inverting regeneration elements. Said respective regeneration elements are disposed in planes roughly perpendicular to said transmission lines. Four consecutive transmission lines disposed on the same level respectively belong to a separate subset of said subsets, and are disposed in a constant order.

### BACKGROUND OF THE INVENTION

1. Field of the Invention

The present invention relates to a system and a method of transmitting data in an electronic circuit, and more particularly in locally synchronous and globally asynchronous type electronic circuits.

2. Description of the Relevant Art

Data is transferred from one synchronous block to another synchronous block. Each synchronous block is clocked by its own clock, of a predetermined frequency. For two synchronous blocks between which data is transmitted, the respective clock frequencies can be the same or different, but have no phase relationship. In other words, the frequencies of these clocks are not in phase.

One way of setting up a connection between two synchronous blocks is to use a mesochronous link, then to change the clock domain using an asynchronous queue of the FIFO (First In First Out) type. A mesochronous link is a data transmission link which ensures a data transfer frequency without imposing a phase relationship between transmission and reception. For this, a set of transmission lines is used, for example a point-to-point one-way communication bus, between a sending element and a receiving element for transmitting data. This data includes data representative of the transmit clock for synchronizing the data on reception.

The data is sent on an edge of the clock signal on transmission of said data, and is sampled on the inverse edge on reception, as illustrated in FIG. 1. As long as the dispersion of the data due to external disturbances or the crosstalk internal to the transmission lines does not exceed half a clock period, the received data can always be synchronized again.

A number of clock cycles can elapse between the moment when data is sent and the moment when it is sampled on reception. There can therefore be a number of data items on the same transmission line at a given time, provided that the data remains spaced in the transmission line.

During the transmission of the data, the data switching edges are scattered about a mean position corresponding to the sending edge of the clock. A time interval must remain in which the data is stable, which ensures that two data packets will not be mixed on transmission. The data set-up time and the data hold time on reception must be included in this time interval. On a set of data transmission lines, every effort is made to transmit as much information as possible, in order to maximize the return on the cost of the set of transmission lines.

The data set-up time represents the minimum duration during which the data must be stable before the active edge of the clock. The data hold time represents the minimum time during which the data present on the input must remain stable on the active edge of the clock to ensure that the data is recognized.

Producing a set of point-to-point transmission lines, for example a point-to-point bus, on an electronic chip entails the use of routers or implementation elements. The routers are used to set up the metallic connections using several metal levels, and to insert in such connections repeaters used to regenerate signal losses. The repeaters minimize signal degradation when the signals are transmitted in metallic wires, and minimize the disturbances associated with capacitive couplings between wires.

For an insulated wire, if there are not enough repeaters, the RC networks, representing the intrinsic resistance and capacitance of the wire, degrade and strongly delay the signal. Conversely, if there are too many repeaters, the delays of the logic gates become too great. It is therefore interesting to obtain a balance between the quality of the signal and the gate delays introduced by the repeaters. In the region of this optimum, the variation in the delays on the signal transmitted according to the distance between repeaters is very low, which allows considerable freedom in adjusting this distance.

The repeaters used can be with or without phase inversion. Repeaters without phase inversion normally have at least two logic layers, which adds an additional latency. Inverting repeaters, however, must be in even numbers, otherwise a signal polarity correction must be provided.

For transmission lines strongly coupled with adjacent lines, it is preferable to have a large number of repeaters, and to find a compromise between the latency and the crosstalk. The latency is often degraded to minimize the crosstalk.

The crosstalk between two transmission lines with a high number of repeaters is strong if the switching edges are overlapping, that is, if the switching edges of the two lines occur roughly simultaneously. In practice, if the respective switching edges of the two lines are offset in time, a switching edge on one produces a small transitional interference effect on the other, but has no direct influence on subsequent switching. However, if the respective switching edges of the two lines are simultaneous, and the transitions are exerted in the same direction, these transitions will mutually accelerate. Conversely, if the respective switching edges of the two lines are simultaneous, and the transitions are exerted in opposite directions, these transitions will mutually slow down.

To take the case of a set of transmission lines, for example a data bus, the problem is more complicated, because a transmission line can be influenced by its immediately adjacent or first adjacent lines, but also, to a lesser extent, by the other lines.

Signal transmission lines that do not switch behave as pseudo-grounds, and groups of lines for which the transmitted signals switch in the same direction synchronously have signals that accelerate more the further they are away from the edge lines of the group, and the greater the number of lines in the group. Similarly, in a group of lines for which the signals transmitted by two immediately adjacent lines switch in opposite directions synchronously, the signals transmitted become that much more delayed the further they are from the edge lines of the group and the greater the number of lines in the group.

An analysis of the contribution of the set of lines of a bus designed on a metallization level to the interferences on one of its transmission lines, demonstrates that most of the disturbances are produced by the two immediately adjacent lines, the other lines having a lesser contribution.

With the trend in silicon chip etching techniques being towards increasingly finer etching, the problems of resistance and capacitive coupling in the interconnections are increasingly critical. There are solutions for reducing these disturbances and their undesirable effects, for example by increasing the width of the transmission lines to reduce their resistance, and/or by increasing the spacing between the transmission lines to reduce the capacitive coupling.

These solutions are, however, costly, because they increase the surface area of the circuits.

There are also methods of compensating for the noises or interferences between two signals by compensating for a noise generated between two repeaters by inverting the phase of one of the two signals on the next repeater. Two signals with the same synchronous transition accelerate, whereas two signals with synchronous transitions in opposite directions slow down.

However, only the disturbances from the immediately adjacent lines are compensated for and, consequently, the relative importance of the other lines increases. Their effect then appears as non-negligible and is not taken into account. Furthermore, the problem is not taken into account in its three dimensions.

### SUMMARY OF THE INVENTION

There is proposed a system of transmitting data in an electronic circuit, including a set of signal transmission lines disposed roughly parallel to each other. Each transmission line includes inverting and non-inverting signal regeneration elements. Said set of transmission lines includes four subsets of lines, and each of said subsets includes at least one transmission line provided with a periodic arrangement of said inverting and non-inverting regeneration elements. Said respective regeneration elements are disposed in planes roughly perpendicular to said transmission lines. Four consecutive or adjacent transmission lines disposed on the same level belong respectively to a separate subset of said subsets, and are disposed in a constant order. A first transmission line of a first of said subsets includes a periodic arrangement of inverting, non-inverting, non-inverting and inverting signal regeneration elements. A second transmission line of a second of said subsets includes a periodic arrangement of inverting, inverting, non-inverting and non-inverting signal regeneration elements. A third transmission line of a third of said subsets includes a periodic arrangement of non-inverting, non-inverting, inverting and inverting signal regeneration elements. A fourth transmission line of a fourth of said subsets includes a periodic arrangement of non-inverting, inverting, inverting and non-inverting signal regeneration elements. The regeneration elements of a periodic arrangement are roughly aligned.

Such a system makes it possible to take account of the disturbances due to the immediately adjacent transmission lines, and furthermore the disturbances due to the second adjacent transmission lines. Each subset includes transmission lines provided with the same periodic arrangement of signal regeneration elements.

Furthermore, two successive signal regeneration elements of a transmission line are spaced at a roughly constant distance.

For an area of such precision, a roughly constant distance means constant to within a maximum of 20%.

In an embodiment, said respective periodic arrangements of said four transmission lines further include at least one set of inverting regeneration elements interposed in each line at the same relative position, said interposed inverting regeneration elements of a set being roughly aligned.

In such a case, the data transmission latency is reduced.

In a first advantageous embodiment, said first transmission line is immediately adjacent to said second transmission line, said second transmission line is immediately adjacent to said third transmission line, and said third transmission line is immediately adjacent to said fourth transmission line.

In a second advantageous embodiment, said first transmission line is immediately adjacent to said fourth transmission line, said fourth transmission line is immediately adjacent to said third transmission line, and said third transmission line is immediately adjacent to said second transmission line.

These two repetitive orders give the best results, due to the alternate sequencing of signal acceleration and slow-down phases.

Advantageously, two transmission lines of the same subset, situated in two consecutive metallization levels, are offset relative to each other.

Disturbances in all three dimensions are then taken into account.

In a first example, said first, second, third and fourth transmission lines respectively belonging to the first, second, third and fourth subsets, and being disposed in a first metallization level, are respectively superimposed on four other transmission lines, of a metallization level consecutive to said first metallization level, said four other transmission lines respectively belonging to the third, fourth, first and second subsets.

In a second example, said first, second, third and fourth transmission lines respectively belonging to the first, fourth, third and second subsets, and being disposed in a first metallization level, are respectively superimposed on four other transmission lines, of a metallization level consecutive to said first metallization level, said four other transmission lines respectively belonging to the third, second, first and fourth subsets.

The disturbances between transmission lines of different metallization levels are then minimized, because the distance between two lines of the same subset belonging to two separate metallization levels separated by an intermediate metallization level is optimized.

Furthermore, the edge lines are ground lines.

These ground lines are used to insulate all the transmission lines from external influences.

In an embodiment, the system includes a clock signal transmission line. In other words, there is a line for transmitting the clock signal.

In a first advantageous embodiment, the system includes processing means for sending data transmitted via a transmission line, different from said clock signal transmission line, on a constant edge of said clock signal, and for sampling said data on the opposite constant edge of said clock signal.

The constant edge is, for example, the rising edge of the clock signal.

For example, said clock signal transmission line is immediately adjacent to one of said ground lines, said clock signal transmission line possibly also being immediately adjacent to a line behaving as a pseudo-ground.

The clock signal is then centered on the time interval including the set-up time added to the data hold time. The margin for sampling the data is then increased.

In a second advantageous embodiment, the system includes processing means for sending data transmitted via a transmission line, different from said clock signal transmission line, and for sampling said data on the same type of edge, rising or falling, as the transmit edge. Said clock signal transmission line includes two immediately adjacent lines each transmitting a signal controlled by control means, each of the two said controlled signals being configured to switch inversely and in phase with said clock signal or not to switch.

It is then possible to impose a delay on the clock signal that is greater than the longest delay on the transmitted data, and so logic is used on just one edge, which simplifies the tests and enables the latency times to be optimized.

Advantageously, the two said immediately adjacent lines each have another immediately adjacent line, different from the clock signal transmission line and second adjacent to said clock signal transmission line, each transmitting a steady-state signal representative of the value of a mode bit used to determine said controlled signal transmitted respectively by the lines immediately adjacent to the clock signal transmission line.

These mode bits, decoded at each signal regeneration element, for example a repeater, are used to determine the presence or absence of switching on the two lines immediately adjacent to the clock signal transmission line, and act as pseudo-grounds.

In an embodiment, the data transmitted by said transmission lines is sent on the rising and falling edges of the clock signal, data sent on a rising edge of the clock signal being sampled on a rising edge of the clock signal, and data sent on a falling edge of the clock signal being sampled on a falling edge of the clock signal.

This means that the data transmission rate can be doubled without increasing the clock frequency.

Advantageously, said processing means are designed to send data transmitted respectively by two immediately adjacent transmission lines, different from said clock signal transmission line, respectively on the rising edges of said clock signal for the first of said two transmission lines and on the falling edges of said clock signal for the second of said two transmission lines. The processing means are also designed to respectively sample said data on the falling edges of said clock signal for the first of said two transmission lines and on the rising edges of said clock signal for the second of said two transmission lines.

There is also proposed a method of transmitting data in an electronic circuit, including a set of signal transmission lines disposed roughly parallel to each other. Each transmission line includes inverting and non-inverting signal regeneration elements. Said set of transmission lines is divided into four subsets of lines, and at least one transmission line provided with a periodic arrangement of said inverting and non-inverting regeneration elements is assigned to each of said subsets. Said respective regeneration elements are disposed in planes roughly perpendicular to said transmission lines, and four consecutive transmission lines respectively belonging to a separate subset of said subsets are disposed in a constant order, at the same level. Inverting, non-inverting, non-inverting and inverting signal regeneration elements are arranged periodically on a first transmission line of a first of said subsets. Inverting, inverting, non-inverting and non-inverting signal regeneration elements are arranged periodically on a second transmission line of a second of said subsets. Non-inverting, non-inverting, inverting and inverting signal regeneration elements are arranged periodically on a third transmission line of a third of said subsets. Non-inverting, inverting, inverting and non-inverting signal regeneration elements are arranged periodically on a fourth transmission line of a fourth of said subsets, and said regeneration elements of a periodic arrangement are roughly aligned.

### BRIEF DESCRIPTION OF THE DRAWINGS

Other objects, characteristics and advantages of the invention will become apparent from reading the description that follows, given by way of non-limiting example, and with reference to the appended drawings in which:

FIG. 1 is a diagrammatic view of a data transmission on a clock signal rising edge with sampling of the data on reception on the falling edge of said clock signal;

FIGS. 2 and 3 are diagrammatic views of embodiments for compensating for the noises from the immediately adjacent lines of a set of transmission lines;

FIG. 4 is a diagrammatic view of a circuit with several metallization levels;

FIG. 5 is a diagrammatic view of an embodiment of a system;

FIGS. 6 to 11 illustrate different cases of immediately adjacent line pairs;

FIGS. 12 and 13 are diagrammatic views of optimum embodiments of a system;

FIG. 14 is a diagrammatic view of an embodiment similar to that of FIG. 12, including additional inverting signal regeneration elements;

FIG. 15 is a diagrammatic view of a circuit with several metallization levels;

FIGS. 16 and 17 illustrate the positioning of two consecutive levels respectively having the same pattern as that of FIGS. 12 and 13;

FIGS. 18 and 19 illustrate three adjacent transmission lines;

FIG. 20 is a diagrammatic view of a circuit with several metallization levels;

FIG. 21 is a diagrammatic view of an embodiment including two steady-state mode bits transmitted on the lines immediately adjacent to the lines immediately adjacent to the clock signal transmission lines;

FIGS. 22 and 23 illustrate an embodiment, in which the data is sent on the rising and falling edges of the clock signal; and

FIG. 24 illustrates a way of implementing the method.

While the invention is susceptible to various modifications and alternative forms, specific embodiments thereof are shown by way of example in the drawings and will herein be described in detail. It should be understood, however, that the drawing and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

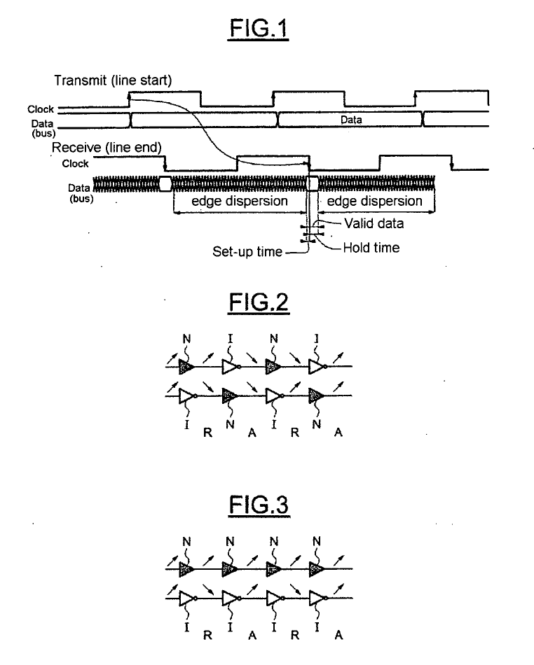

FIG. 1 illustrates a data transmission on a unidirectional communication bus. The clock signal on transmission at the start of the line is represented, as is the clock signal on reception at the end of the line. The data is sent on rising edges of the clock signal and sampled on reception on falling edges of the clock signal. During the data transmission, the transmitted data is scattered around a mean position corresponding to the transmit edge of the clock, in this case the rising edge.

FIGS. 2 and 3 represent two patterns for compensating for the noises from the immediately adjacent transmission lines.

FIG. 2 shows two immediately adjacent transmission lines of the same level. The repeaters are evenly spaced and located at identical respective abscissae. The first line includes a repetitive sequence of non-inverting repeater N, inverting repeater I, non-inverting repeater N and inverting repeater I. Correspondingly, the second line includes a repetitive sequence of inverting repeater I, non-inverting repeater N, inverting repeater I and non-inverting repeater N.

The example shown includes two initial rising transitions. There is then a signal slow-down phase R followed by a signal acceleration phase A, followed by a signal slow-down phase R and followed by a signal acceleration phase A. Ultimately, the noise due to the immediately adjacent lines is compensated.

In FIG. 3, two immediately adjacent transmission lines of the same level are represented. The repeaters are evenly spaced and located at identical respective abscissae. The first line includes a repetitive sequence of non-inverting repeaters N. Correspondingly, the second line includes a repetitive sequence of inverting repeaters I.

The example shown includes two initial rising transitions. There is then a signal slow-down phase R followed by a signal acceleration phase A, followed by a signal slow-down phase R and followed by a signal acceleration phase A. Ultimately, the noise due to the immediately adjacent lines is compensated.

FIGS. 2 and 3 illustrate the case of two rising edge transitions. Naturally, all the other cases devolve directly from this, because the inversion of one of the input signals inverts all the signals of the corresponding transmission line, and therefore inverts the acceleration and slow-down sections.

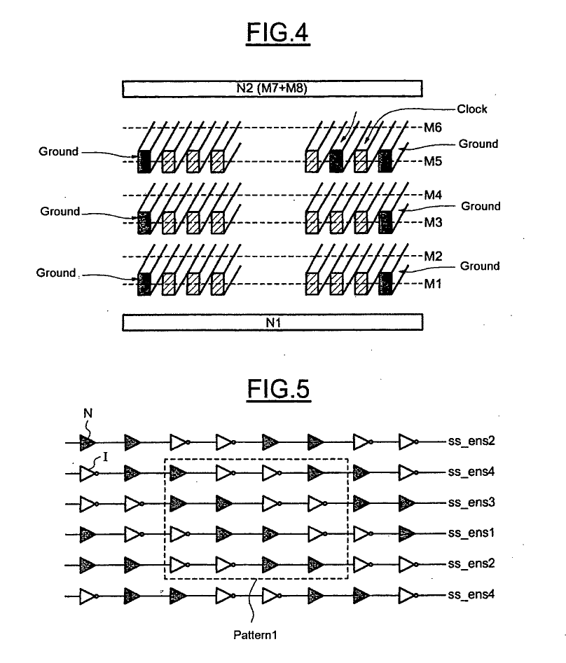

An example of integrated circuits used to implement the invention is represented in FIG. 4.

In the examples that follow, the integrated circuits include eight metallization levels M1, M2, M3, M4, M5, M6, M7 and M8, two of which, M7 and M8, are levels normally reserved for a complete power and ground plane, represented in a layer N2. The ground plane N1 formed by the substrate is also represented. In reality, the repeaters are located in the ground plane N1.

The metallization levels in a circuit are in roughly parallel planes, whose representation has been arbitrarily chosen to be horizontal. A short vertical connection between two horizontal metallization levels is called a via.

In the examples described, the odd metallization levels M1, M3 and M5 are assigned to the production of horizontal wires of a data transmission bus in the same direction and the even levels M2, M4 and M6 to the production of horizontal wires perpendicular to the direction of the horizontal wires of the bus.

Normally, for a given metallization level, there is a preferred routing direction, in other words, for a given metallization level, the wires are oriented almost exclusively in the same direction. For a straight-line portion of a bus, the metallization levels having a preferred direction matching that of the straight-line portion are used.

In other words, the metallization levels in a circuit are in parallel planes whose representation has been arbitrarily chosen to be horizontal. The vertical transition from one plane to another is achieved by a short vertical metallization called a via. In a given metallization plane, numerous wires have been generated using routing software. These wires generated by the routers use two directions perpendicular to the metallization plane, which can arbitrarily be called left/right and up/down, corresponding to the conventional representation of a routing in two dimensions. For reasons of efficiency, it is accepted that, for a metallization level, there is a preferred routing direction, that is, that most of the wires have segments oriented almost exclusively in only one direction, left/right or up/down, and, normally, the preferred direction of a level will be orthogonal to that of the two adjacent levels.

The last two levels are thicker and are used to obtain less resistive connections. However, since these levels are thicker, the connections produced must be less dense, with wider and more widely spaced wires. Since such wires are more expensive, they are used only for special routings such as the power supplies or for the wires conducting high currents. It is therefore assumed in the examples described, that the last two levels are dedicated almost exclusively to the power or ground planes. It is assumed that the buses are routed on the remaining levels. The repeaters for boosting and regenerating the signals in the wires will be found in the bottom layers.

In the example described, two consecutive metallization levels have transmission lines having perpendicular directions.

The interactions between transmission lines of perpendicular directions, situated in two consecutive metallization levels, represent a coupling area that is negligible compared to the coupling area of two parallel wires over a distance of several millimeters.

In practice, in a bus, numerous transmission lines are parallel over a significant distance of several millimeters, which creates a coupling capacitance, between two parallel lines, of several thousand square microns, far greater than the coupling capacitance between two perpendicular lines.

Of course, as a variant, all the metallization levels can have the same preferred direction.

The transmission lines of the data bus are represented on the odd metallization levels. In this example, lines, the section of which is shaded, are used as grounds: Ground, and a data transmission line is used to transmit the clock signal: Clock. The other transmission lines represented are used to transmit the data to be transmitted over the bus.

Since the signals on the bus are insulated laterally, the only disturbances to be considered are the disturbances internal to the bus, that is, between signals, for which the location in time and space can be predicted.

The grounds used to insulate the transmission lines of the bus are wires having geometrical characteristics similar to the other wires but being regularly connected to the ground planes N1, N2 to minimize the resistance to ground.

The metallic levels are saturated, there is no space left for routing a transmission line that does not belong to the bus other than perpendicularly to the direction of the bus, this being valid in all the space delimited by all the shielding grounds and the ground planes N1 and N2.

The clock signal is also protected from the lateral influences.

In practice, even if a disturbance can be identical for all the signals, it has a different effect on the edge of the clock signal used for sampling and the data signals, since it does not switch at the same time. The disturbances internal to the bus bring into play coupling areas of the order of ten or so thousand square millimeters, whereas a wire perpendicular to a link represents a coupling area of less than one square micrometer. Even the presence of ten or so such intersections is therefore negligible.

The intermediate metallization levels M1, M2, M3, M4, M5, M6 each include a set of parallel metallic wires.

FIG. 5 represents an example of disposition of transmission lines of the same level. Each transmission line includes inverting I and non-inverting N signal regeneration elements. The respective regeneration elements are disposed in planes roughly perpendicular to the transmission lines.

The set of transmission lines is divided into four subsets ss_ens1, ss_ens2, ss_ens3 and ss_ens4 of transmission lines, each subset including transmission lines having the same periodic arrangement of signal regeneration elements.

Four adjacent transmission lines disposed at the same level respectively belong to a separate subset of the four subsets ss_ens1, ss_ens2, ss_ens3 and ss_ens4. Transmission lines belonging to the same level are disposed in a constant order. In other words, the latter are disposed in a cyclic order.

A transmission line of the first subset ss_ens1 includes a periodic arrangement of inverting I, non-inverting N, non-inverting N and inverting I signal regeneration elements.

A transmission line of the second subset ss_ens2 includes a periodic arrangement of inverting I, inverting I, non-inverting N and non-inverting N signal regeneration elements.

A transmission line of the third subset ss_ens3 includes a periodic arrangement of non-inverting N, non-inverting N, inverting I and inverting I signal regeneration elements.

A transmission line of the fourth subset ss_ens4 includes a periodic arrangement of non-inverting N, inverting I, inverting I and non-inverting N signal regeneration elements.

The respective regeneration elements of the different transmission lines are respectively aligned.

The embodiment of FIG. 5 has the following repetitive order: a transmission line of the fourth subset ss_ens4, a transmission line of the third subset ss_ens3, a transmission line of the first subset ss_ens1 and a transmission line of the second subset ss_ens2.

The basic pattern Pattern1 includes four sub-patterns which are periodic arrangements of signal regeneration elements of the transmission lines respectively belonging to the fourth, third, first and second subsets ss_ens1, ss_ens2, ss_ens3 and ss_ens4.

Transmission lines of the same level are disposed in a constant, or cyclic, order.

As a variant, this order of disposition can be different, but remains a constant order.

In each of the variants, two signal acceleration sections and two signal slow-down sections are obtained.

In practice, two adjacent signals with two transitions in the same direction simultaneously accelerate, whereas two adjacent signals with two transitions in opposite directions simultaneously slow down.

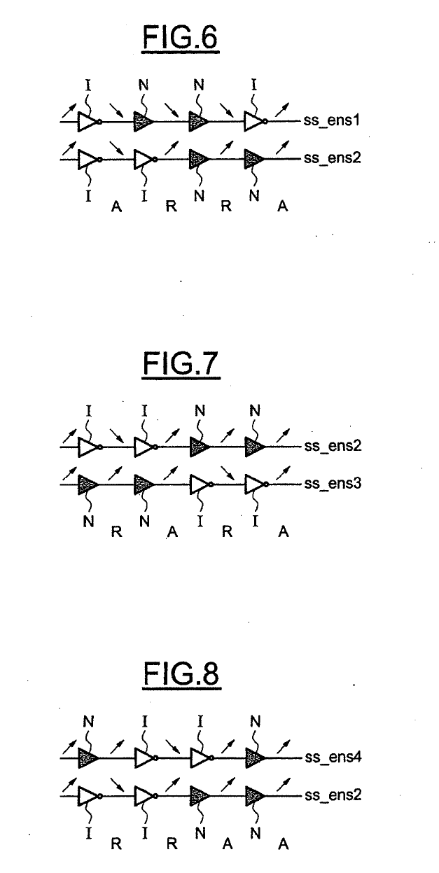

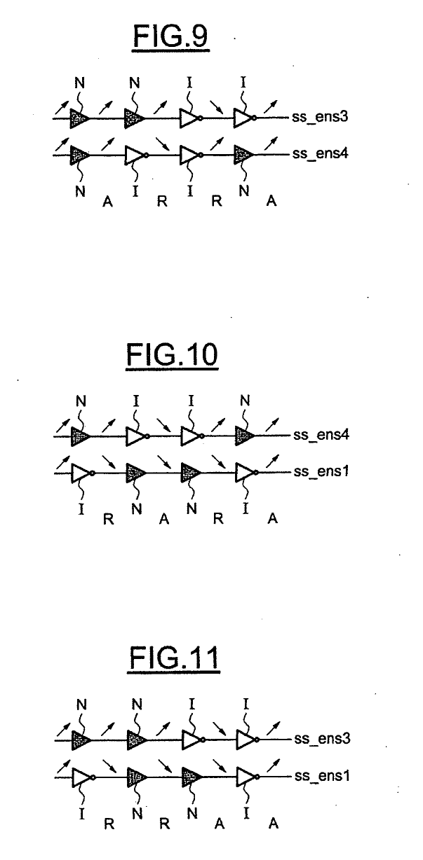

As illustrated in FIGS. 6 to 11, in the case of two rising edge transitions at the input, FIGS. 8 and 11 illustrate the immediately adjacent lines for which two acceleration sections A alternate with two slow-down sections R, and these cases must be avoided. However, even if it is essential to avoid having a transmission line of the first subset ss_ens1 immediately adjacent to a transmission line of the third subset ss_ens3, and to avoid having a transmission line of the second subset ss_ens2 immediately adjacent to a transmission line of the fourth subset ss_ens4, they can, however, be second adjacent.

For the same level, keeping such a constant order of disposition of the transmission lines is a way of compensating for the crosstalk between immediately adjacent lines and between second adjacent lines.

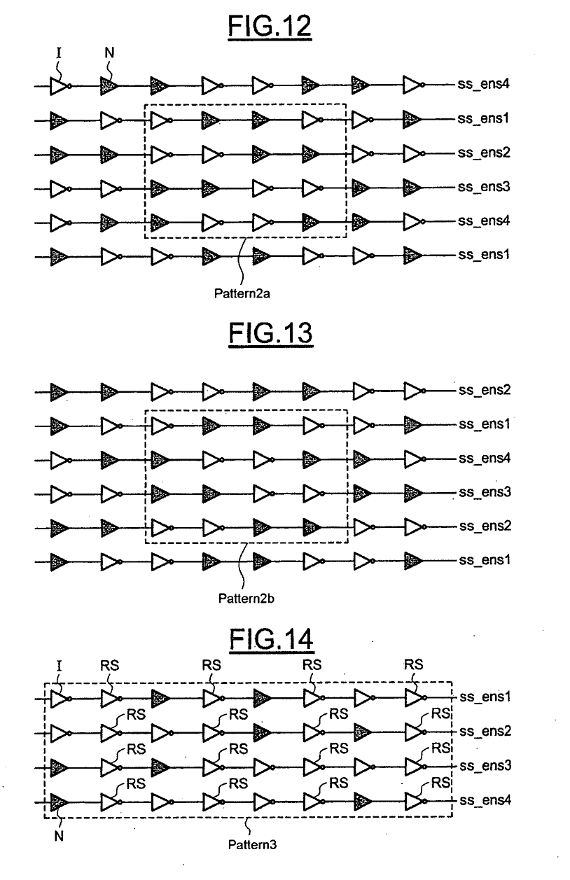

In light of the above, two preferred patterns are illustrated in FIGS. 12 and 13.

FIG. 12 illustrates an embodiment, in which slow-downs and accelerations follow alternately for two immediately adjacent lines. The basic pattern Pattern2a includes a repetitive order of a transmission line of the first subset ss_ens1, a transmission line of the second subset ss_ens2, a transmission line of the third subset ss_ens3, and a transmission line of the fourth subset ss_ens4.

FIG. 13 illustrates another embodiment, in which slow-downs and accelerations follow alternately for two immediately adjacent lines. The basic pattern Pattern2b includes a repetitive order of a transmission line of the first subset ss_ens , a transmission line of the fourth subset ss_ens4, a transmission line of the third subset ss_ens3, and a transmission line of the second subset ss_ens2.

These two patterns avoid having a transmission line of the first subset ss_ens1 immediately adjacent to a transmission line of the third subset ss_ens3, and/or having a transmission line of the second subset ss_ens2 immediately adjacent to a transmission line of the fourth subset ss_ens4. Thus, the immediately adjacent lines have acceleration and slow-down sections which are compensated by successive alternation.

As a variant, as illustrated in FIG. 14, additional inverting repeaters RS are interposed between the signal regeneration elements, or repeaters, in each line at the same relative position.

The basic pattern Pattern3 illustrated corresponds to that of FIG. 12 (Pattern2a), in which, between two successive repeaters, there is interposed an inverting repeater I. Of course, these inverting repeaters cannot be interposed between all the successive repeaters of FIG. 12. However, when an additional inverting repeater RS is interposed between two signal regeneration elements of the lines of a subset, an additional inverting repeater RS is also interposed between the two respective signal regeneration elements of the transmission lines of the other subsets.

This provides a latency gain.

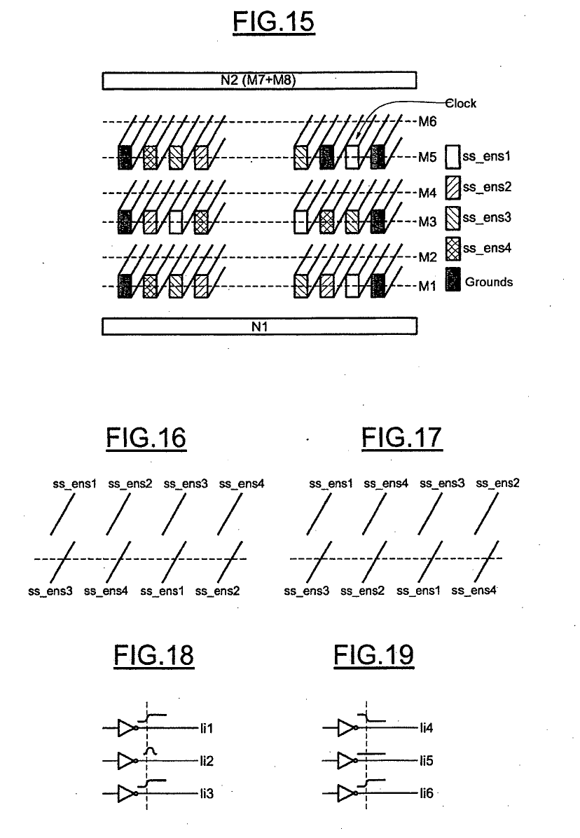

FIG. 15 illustrates an exemplary embodiment of a system, in three dimensions.

On a metallization level, a chosen order is followed, preferably the pattern Pattern2a, the optimal order of FIG. 12. This order is defined once for all, and is used for all the odd metallization levels.

Furthermore, for two successive odd metallization levels, the relative positions of two lines belonging to the same subset are offset by two positions, such that two transmission lines belonging to the same subset are as far apart as possible from each other. Thus, the few lines that are not compensated correspond to very weak couplings. The clock signal is assigned to one of these subsets according to its position. Such a disposition is illustrated in FIG. 16. As a variant, FIG. 17 illustrates the case in which the pattern 2b of FIG. 13 is chosen on an odd metallization level.

Such a device can be used, not only to reduce the interferences associated with the immediately adjacent lines, but also to reduce the residual interferences due to the second adjacent lines in a metallization level.

In a vertical direction perpendicular to that of a metallization level, although the couplings remain relatively weak, the interferences are also reduced on most of the couplings in this direction.

A signal transmitted on a transmission line surrounded by first adjacent lines transmitting a signal that does not switch, is accelerated relative to a shielded clock signal. The term shielded clock signal is used to mean a clock signal framed by two ground lines.

A line transmitting a signal that does not switch does not behave as a true ground, but as a pseudo-ground, that is, a wire that does not switch, at least when it is essential to have a pseudo-ground behavior. This wire, having its own resistance, is connected to a repeater having its own internal resistance, and at a distance remote from the repeater, the resistance of this pseudo-ground, relative to the absolute ground, can be relatively high.

When such a pseudo-ground is surrounded by two wires that switch simultaneously in opposite directions, since the signal on this intermediate wire does not vary, this pseudo-ground behaves as a true ground. However, in the other cases, the pseudo-ground slows down the signals less than a true ground would, so if an average clock signal transfer time is desired, at least one pseudo-ground will be used on a line adjacent to the clock signal transfer line, because to surround the latter with two grounds would slow down the clock signal too much, and it would be slower than the average of the signals. FIG. 18 shows three adjacent transmission lines li1, li2 and li3, the middle line li2 of which transmits a signal that does not switch. In the case where the two signals carried by the other two lines li1 and li3 switch in the same direction at the same time, they induce a spurious signal on the middle line li2. These two signals therefore accelerate even via the intermediate transmission line li2 (effect of the second adjacent line).

However, as illustrated in FIG. 19, if two signals, transmitted by two transmission lines li4 and li6 separated by an intermediate line li5 transmitting a signal that does not switch, switch in inverse directions at the same time, the intermediate line li5 remains virtually stable and then behaves as a ground, and there is therefore a separation of the signals.

When the acceleration and separation sections alternate, the resultant effect is a slight acceleration of the signals. The term separation section is used to mean a section on which a pseudo-ground behaves as a true ground.

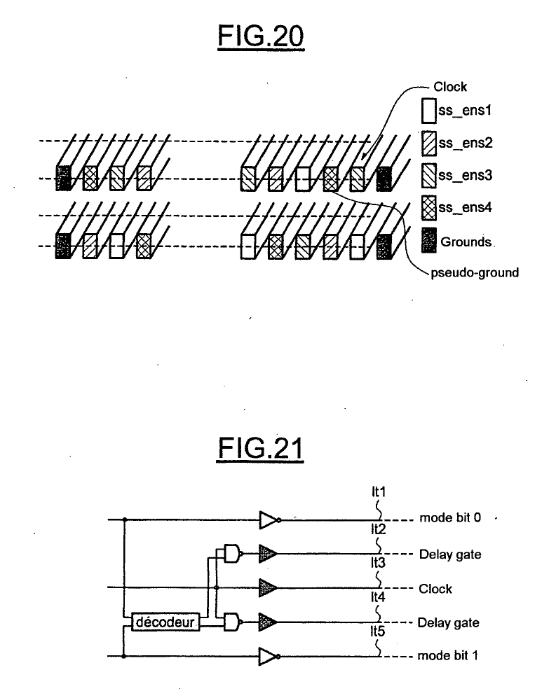

Since on average the data signals are transmitted more quickly than the shielded clock signal, it is interesting to accelerate the transmission of the clock signal. Accelerating the transmission of the clock signal can be achieved either by increasing the distance between the clock signal transmission line and the first adjacent transmission lines transmitting the ground signals, or by transmitting over the first adjacent lines of the clock signal transmission line signals that do not switch while the sampling edge is switching. Now, in the case of a mesochronous link, with a sampling edge different from the sending edge, the sampling edge “travels alone”. In other words, when the sampling edge arrives at a given point on the link, the edges on the adjacent data are already passed. If slightly accelerating this edge is then desired, all that is needed is a ground on one side of the clock signal and data on the other which will behave as a pseudo-ground when the edge passes, as illustrated in FIG. 20.

When data is sent on a clock edge and this data is sampled on the other edge on reception, every effort is made to position the clock signal so as to center the sampling edge in the middle of the data stability interval (set-up time+hold time). This amounts to centering the clock edge corresponding to the sending of the data in relation to the various data switching edges at the end of transmission, that is, the clock must have a propagation time that is as near as possible to the average of the data propagation times.

When all the repeaters are identical (no noise compensation), it can be shown that the average propagation time corresponds approximately to the propagation time of a line framed by two grounds. With the noise compensation by the patterns described previously, the average behavior of the signal tends to accelerate slightly, so it is essential to accelerate the sampling edge of the clock accordingly, for example by placing the clock transmission line alongside a line that behaves as a pseudo-ground for this edge.

Sampling the data on reception on the inverse clock edge is a way of adjusting the physical device if the performance characteristics are too tight. In practice, by slightly lowering the frequency, the constraints can be relaxed both on the set-up time and on the hold time for sampling.

Crosstalk is not the only cause of data dispersion, deviations between wires or simply the dispersions inherent to the fabrication process are also to blame.

However, crosstalk remains the major, and the least predictable, cause of data dispersion. The propagation delay in a metallic wire depends on the distribution of its resistance and its capacitance. Since the temperature variation of a metallic resistance is almost twice as weak as the temperature variation of the equivalent resistance of an MOS transistor, the delays in the wires will be more stable relative to the temperature variation than the delays of the MOS gates. Similarly, the relative variations of geometry, such as variations of wire widths or wire spacing, on long wires are smaller than the relative variations on the MOS transistors that include the repeaters. This also helps to make the wire delays more reliable. As a variant, the data is sampled on the same edge type as the sending edge of said data. A delayed clock is then used, and it is then fully advisable to use a delay that is as close as possible to the delay on the data transmission. For the reasons stated previously, a gate delay alone would not be appropriate. The delay must include the same gate delay as for the data transmission, and a wire delay at least equivalent to the worst crosstalk case possible on the data transmission, while also taking into account the noise compensation so as not to be too pessimistic.

FIG. 12 illustrates a device for adjusting the clock signal in which are added at least two bits (mode bits) for programming the delay of the clock signal: these bits are positioned on initialization of the circuit, and therefore act as a pseudo-ground to protect the device.

These mode bits transmitted on the lines lt1, lt5, decoded at each repeater, are used to determine the presence or absence of switching of the signals transmitted over the two lines lt2, lt4 immediately adjacent to the clock signal transmission line lt3.

On each section, a choice can be made either to shield the clock signal (no programming), or to surround it by two adjacent signals that do not switch (low acceleration), or to use a programming of the delay by ordering or not ordering a switching of one of the two adjacent signals. Clearly, the clock signal transmission line lt3 keeps the same number of inverting repeaters I and non-inverting repeaters N as the other transmission lines, but the immediately adjacent transmission lines lt2, lt4 have imposed transitions.

FIG. 21 represents the case of a programmable section.

In this section with programming, the delay gates are activated or not according to the decoding of the mode bits or programming bits. The repeater of the section of the clock signal transmission line includes a non-inverting repeater, and therefore the transmission lines also behave as delay gates.

If the margin on the clock delay relative to the transmitted data is adjusted as tightly as possible and if the dispersion on the data is significantly less than half the clock cycle time, both edges can be used and the rate can be doubled. The data is sent alternately on the rising edge and on the falling edge, the data sent on the rising edge being sampled on the rising edge and the data sent on the falling edge being sampled on the falling edge.

It is also possible to stagger the switching edges using delays: when the switching edges are separated, there is first of all a maximum of disturbances on the immediately adjacent lines, then, when the transition intervals are separated, a minimum disturbance is obtained.

In the case of a mesochronous link, an increase in the latency to be able to increase the switching frequency is perfectly possible. The transition edges between the signals transmitted by the transmission lines belonging to two subsets with lines immediately adjacent can therefore be separated. The transmission lines are separated into two groups of lines grp1, grp2 so that two immediately adjacent lines of the same level do not belong to the same group of transmission lines.

The transitions between these two groups grp1, grp2 are separated so as to be at the limit of the overlap of the signal transition periods of the various groups. The delay added, for example, on the first group will be added on the second group before sampling. The latency is therefore increased by the value of the delay, but the sampling frequency which is a function only of the dispersion of the data in each group is improved.

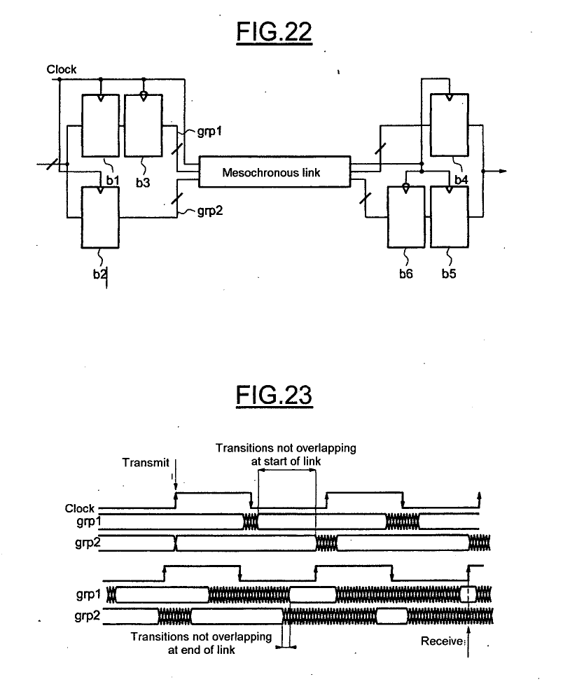

FIG. 22 represents a device that does not use delay on the clock signal. Half of the grp1 data is then sent on a clock edge by means of the flip-flop b 1, and the other half grp2 on the other edge by means of the flip-flop b2, each half of the data being sampled on the inverse edge of the sending edge, as illustrated in FIG. 23. The grp1 data transmitted on a falling edge has a half clock cycle delay at the outset due to the flip-flop b3, and is sampled on a rising edge on reception, by means of the flip-flop b4. The grp2 data transmitted on a rising edge is sampled on a falling edge by means of a flip-flop b5 and delayed by half a clock cycle by means of the flip-flop b6 to be aligned on the other half of the grp1 data. The crosstalk problems on the second adjacent transmission lines are reduced by using a pattern as described previously, for example a pattern Pattern2a or Pattem2b.

There is therefore a compensation not only with the second adjacent transmission lines of the same level, but also a compensation with the nearest adjacent lines of a metallization layer including transmission lines in the same direction.

At the start of the transmission, the transition edges are separated, and the residual disturbances (vertical and on the second adjacent) are compensated. At the end of transmission, the transitions between the lines of the first group and the lines of the second group overlap, and the compensation therefore acts on the immediately adjacent lines.

The timing diagrams of FIG. 23 illustrate the improvement in the noise compensation by using, in addition, pseudo-grounds as explained previously. The use of pseudo-grounds improves the reduction of the crosstalk at the start of the transmission, as long as the signals are not overlapping.

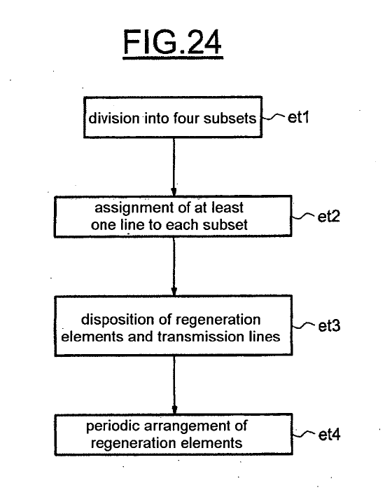

FIG. 24 illustrates a way of implementing the method.

Said set of transmission lines is divided into four subsets of lines (step et1), and at least one transmission line provided with a periodic arrangement of said inverting and non-inverting regeneration elements is assigned to each of said subsets (step et2).

Furthermore, said respective regeneration elements are disposed in planes roughly perpendicular to said transmission lines, and four adjacent transmission lines respectively belonging to a separate subset of said subsets are disposed in a constant order, at the same level (step et3).

Finally (step et4), inverting, non-inverting, non-inverting and inverting signal regeneration elements are arranged periodically on a first transmission line of a first of said subsets. Inverting, inverting, non-inverting and non-inverting signal regeneration elements are arranged periodically on a second transmission line of a second of said subsets. Non-inverting, non-inverting, inverting and inverting signal regeneration elements are arranged periodically on a third transmission line of a third of said subsets. Non-inverting, inverting, inverting and non-inverting signal regeneration elements are arranged periodically on a fourth transmission line of a fourth of said subsets, and said first, second, third and fourth respective regeneration elements of said periodic arrangements are roughly aligned.

The method can be used to reduce the crosstalk in an integrated circuit.

The method can be used to minimize, not only the disturbances due to the immediately adjacent transmission lines, but also the disturbances due to the second adjacent transmission lines.

Further modifications and alternative embodiments of various aspects of the invention may be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description to the invention. Changes may be made in the elements described herein without departing from the spirit and scope of the invention as described in the following claims. In addition, it is to be understood that features described herein independently may, in certain embodiments, be combined.

What is claimed is:

1. System of transmitting data in an electronic circuit, comprising a set of signal transmission lines disposed roughly in parallel to each other, each transmission line comprising inverting and non-inverting signal regeneration elements, wherein:
said set of transmission lines comprises four subsets of lines;
each of said subsets comprises at least one transmission line provided with a periodic arrangement of said inverting and non-inverting regeneration elements;
said respective regeneration elements are disposed in planes roughly perpendicular to said transmission lines;
four consecutive transmission lines disposed on the same level belong respectively to a separate subset of said subsets, and are disposed in a constant order;
a first transmission line of a first of said subsets comprising a periodic arrangement of inverting, non-inverting, non-inverting and inverting signal regeneration elements, a second transmission line of a second of said subsets comprising a periodic arrangement of inverting, inverting, non-inverting and non-inverting signal regeneration elements, a third transmission line of a third of said subsets comprising a periodic arrangement of non-inverting, non-inverting, inverting and inverting signal regeneration elements, and a fourth transmission line of a fourth of said subsets comprising a periodic arrangement of non-inverting, inverting, inverting and non-inverting signal regeneration elements, said regeneration elements of a periodic arrangement being roughly aligned.

2. System according to claim 1, in which two successive signal regeneration elements of a transmission line are spaced at a roughly constant distance.

3. System according to claim 1, in which said respective periodic arrangements of said four transmission lines further comprise at least one set of inverting regeneration elements interposed in each line at the same relative position, said interposed inverting regeneration elements of a set being roughly aligned.

4. System according to claim 1, in which said first transmission line is immediately adjacent to said second transmission line, said second transmission line is immediately adjacent to said third transmission line, and said third transmission line is immediately adjacent to said fourth transmission line.

5. System according to claim 1, in which said first transmission line is immediately adjacent to said fourth transmission line, said fourth transmission line is immediately adjacent to said third transmission line, and said third transmission line is immediately adjacent to said second transmission line.

6. System according to claim 1, in which two transmission lines of the same subset, situated in two consecutive metallization levels, are offset relative to each other.

7. System according to claim 6, in which said first, second, third and fourth transmission lines respectively belonging to the first, second, third and fourth subsets, and being disposed in a first metallization level, are respectively superimposed on four other transmission lines, of a metallization level consecutive to said first metallization level, said four other transmission lines respectively belonging to the third, fourth, first and second subsets.

8. System according to claim 6, in which said first, second, third and fourth transmission lines respectively belonging to the first, fourth, third and second subsets, and being disposed in a first metallization level, are respectively superimposed on four other transmission lines, of a metallization level consecutive to said first metallization level, said four other transmission lines respectively belonging to the third, second, first and fourth subsets.

9. System according to claim 1, in which the edge lines are ground lines.

10. System according to claim 1, comprising a clock signal transmission line.

11. System according to claim 10, comprising processing means for sending data transmitted via a transmission line, different from said clock signal transmission line, on a constant edge of said clock signal, and for sampling said data on the opposite constant edge of said clock signal.

12. System according to claim 9, in which said clock signal transmission line is immediately adjacent to one of said ground lines.

13. System according to claim 9, comprising processing means for sending data transmitted via a transmission line, different from said clock signal transmission line, and for sampling said data on the same type of edge, rising or falling, as the transmit edge, in which said clock signal transmission line comprises two immediately adjacent lines each transmitting a signal controlled by control means, each of the two said controlled signals being configured to switch inversely and in phase with said clock signal or not to switch.

14. System according to claim 13, in which the two said immediately adjacent lines each have another immediately adjacent line, different from the clock signal transmission line and second adjacent to said clock signal transmission line, each transmitting a steady-state signal representative of the value of a mode bit used to determine said controlled signal transmitted respectively by the immediately adjacent lines of the clock signal transmission line.

15. System according to claim 13, in which the data transmitted by said transmission lines is sent on the rising and falling edges of the clock signal, data sent on a rising edge of the clock signal being sampled on a rising edge of the clock signal, and data sent on a falling edge of the clock signal being sampled on a falling edge of the clock signal.

16. System according to claim 11, in which said processing means are designed to send data transmitted respectively by two immediately adjacent transmission lines, different from said clock signal transmission line, respectively on the rising edges of said clock signal for the first of said two transmission lines and on the falling edges of said clock signal for the second of said two transmission lines, and designed to respectively sample said data on the falling edges of said clock signal for the first of said two transmission lines and on the rising edges of said clock signal for the second of said two transmission lines.

17. Method of transmitting data in an electronic circuit, comprising a set of signal transmission lines disposed roughly parallel to each other, each transmission line comprising inverting and non-inverting signal regeneration elements, wherein:
said set of transmission lines is divided into four subsets of lines;
at least one transmission line provided with a periodic arrangement of said inverting and non-inverting regeneration elements is assigned to each of said subsets;
said respective regeneration elements are disposed in planes roughly perpendicular to said transmission lines;
four consecutive transmission lines respectively belonging to a separate subset of said subsets are disposed in a constant order, at the same level;
inverting, non-inverting, non-inverting and inverting signal regeneration elements are arranged periodically on a first transmission line of a first of said subsets, inverting, inverting, non-inverting and non-inverting signal regeneration elements are arranged periodically on a second transmission line of a second of said subsets, non-inverting, non-inverting, inverting and inverting signal regeneration elements are arranged periodically on a third transmission line of a third of said subsets, non-inverting, inverting, inverting and non-inverting signal regeneration elements are arranged periodically on a fourth transmission line of a fourth of said subsets, and said regeneration elements of a periodic arrangement are roughly aligned.
